(19) United States
(12) Patent Application Publication
(10) Pub. No.: US 2013/0130508 A1
(43) Pub. Date: May 23, 2013

(54) Compositions and Methods for Texturing of Silicon Wafers

(71) Applicants: Aiping Wu, Macungie, PA (US); Madhukar Bhaskara Rao, Fogelsville, PA (US); Dnyanesh Chandrakant Tamboli, Breingsville, PA (US)

(72) Inventors: Aiping Wu, Macungie, PA (US); Madhukar Bhaskara Rao, Fogelsville, PA (US); Dnyanesh Chandrakant Tamboli, Breingsville, PA (US)

(73) Assignee: Air Products and Chemicals, Inc., Allentown, PA (US)

(21) Appl. No.: 13/475,632

(22) Filed: May 18, 2012

Related U.S. Application Data
(60) Provisional application No. 61/530,760, filed on Sep. 2, 2011.

(51) Int. Cl. H01L 21/306

(52) U.S. Cl. CPC H01L 21/30604
USPC 438/753; 252/79.1; 252/79.3; 252/79.4

(57) ABSTRACT

Texturing composition for texturing silicon wafers having one or more surfactants. Methods of texturing silicon wafers having the step of wetting said wafer with a texturing composition having one or more surfactants.

### CROSS-REFERENCE TO RELATED APPLICATIONS

This Application claims the benefit of Provisional U.S. patent application Ser. No. 61/530,760 filed Sep. 2, 2011 (Attorney Docket No. 07482Z2), U.S. patent application Ser. No. 13/296836 filed Nov. 15, 2011 (Attorney Docket No. 07482Z2P) and U.S. application Ser. No. 61/416998 (Attorney Docket No. 07482Z) filed Nov. 24, 2010, all of which are incorporated by reference in their entirety.

### BACKGROUND OF THE INVENTION

This invention relates to texturing of a surface of a silicon wafer. For improving the efficiency of conversion of light energy to electricity, a very low reflecting silicon surface is desired. For monocrystalline silicon for example, this is achieved by anisotropic etching of (100) Si wafers to form pyramid structures on the surface, in a process called as texturing. A uniform and dense distribution of pyramids is desired on the surface of the silicon wafer to achieve low reflectance. It is desired that the pyramid heights be less than 10 μm and be uniform in size. Smaller and uniform pyramid structures ensure good coverage by the passivation layer which is deposited on the top of the textured surface again to prevent losses in efficiency. Smaller and uniform pyramid structures also ensure that metal contact lines printed on the silicon surface are narrower, allowing more light to pass through to the silicon surface for the photo-electron conversion.

For multicrystalline silicon, the surface is typically etched using an alkaline or acidic solution to form pits or pores on the surface. The pits typically have a diameter and a depth less than 15 μm. A uniform distribution of the pores is desired on the surface of the silicon wafer to achieve low reflectance. The roughness of the surface decreases the reflectivity of the wafer and increases the length of the path traveled by the light inside the material, and therefore increases the effectiveness of the transformation of light to electricity.

Prior art references include: WO 2009120631 A2, CN 101634026 A, CN 101634027 A, DE 102007058829 A1, WO 2009119995 A2, U.S. Pat. No. 4,137,123 A, CN 101217173 A, CN 1983644 A, CN 1983645 A, JP 2009123811 A, EP 944114 A2, EP 1890338 A1, Basu, P. K. et al, Solar Energy Materials & Solar Cells (2010), 94(6), 1049-1054, Basu, P. K. et al, Renewable Energy (2009), 34(12), 2571-2576, WO 2009071333, Gangopadhyay, U. et al., Solar Energy Materials & Solar Cells (2006), 90(18-19), 3094-3101; WO 2008022671; U.S. Pat. No. 5,949,123; U.S. Pat. No. 6,340,640 B1, US 2003/0119332 A1, US2111/0059570 A1, US 2006/0068597 A1, U.S. Pat. No. 7,192,885 B2, F. Duerinchx, L. Frisson, P. P. Michies et al, “Towards highly efficient industrial cells and modules from polycrystalline wafers”, published at the 17th European Photovoltaic Solar Energy conference, Oct. 22-26, 2001, Munich, Germany, EP 2 006 892 A1, US 2007/0151944 A1, U.S. Pat. No. 7,759,258 B2, WO 2009/119995, WO 2010/107863 A1, US2010/0239818 A1, WO 2011/032880 A1, M. Lipinski et al, “Reduction of surface reflectivity by using double porous silicon layers”, Materials Science and Engineering, B101 (2003) 297-299, D. H. Macdonald, et al, “Texturing industrial multicrystalline silicon solar cells”, Solar Energy, 76 (2004), 277-283.

There is still a need in the art for texturing compositions and methods of texturing that provide silicon wafers having reduced reflectance and desirable amounts of silicon loss when processing the silicon wafers, that is also independent of the source of the wafer. Since there is a large variety of monocrystalline and multicrystalline wafer suppliers and variety in the wafers supplied by different suppliers, for example, different structure defect density, grain quality, and degree of saw damage in the wafers, it is desired to have a texturing process that is not dependent on the source of the wafers and provides consistent results including low reflectance and desirable amounts of Si loss, with wafers from different suppliers.

### BRIEF SUMMARY OF THE INVENTION

Compositions of this invention can be used to treat silicon wafers or substrates (the terms silicon wafers and substrates will be used interchangeably herein) in the texturing processes of this invention. The silicon wafers treated in accordance with these inventions may be used to make photovoltaic cells. Wafers subjected to compositions and/or methods of this invention may show improvement in the texturing uniformity and reduced reflectivity compared to the wafers not subjected to this treatment. Additional benefits that may be achieved with the method and/or composition of this invention may include one or more of the following: (1) the creation of uniform and smaller oval pits on the surface of the wafer with desirable Si loss; (2) decreased reflectance of the textured surface; and (3) consistent texturing results on silicon wafers from different suppliers.

It is desirable to have as low reflectivity as possible. Our invention provides compositions and methods to improve the texturing of the surface of the wafer. Our invention involves treating the wafer surface with a composition or compositions that comprises one or more surfactants in an acidic texturing solution. The composition modifies the wafer surface by creating smaller and uniform pits on the silicon wafer surface with desirable Si loss, resulting in improved uniformity of the textured surface that results in lower surface reflectivity.

This invention is a texturing composition for texturing silicon wafers comprising consisting essentially of or consisting of one or more acids, one or more anionic surfactants (for example anionic sulfur-containing surfactants) and water (typically the balance is water) and methods of using those compositions to texture wafers.

The anionic sulfur-containing surfactants useful in the texturing composition may be one or more selected from the group consisting of linear alkylbenzenesulfonates (LAS), secondary alkylbenzenesulfonate, lignin sulfonates, N-acyl-N-alkyltaurates, fatty alcohol sulfates (FAS), petroleum sulfonates, secondary alkanesulfonates (SAS), paraffin sulfonates, fatty alcohol ether sulfates (FAES), α-Olefin sulfonates, sulfosuccinate esters, alkylnapthalenesulfonates, isethionates, sulfuric acid esters, sulfated linear primary alcohols, sulfated polyoxyethylenated straight chain alcohols, sulfated triglyceride oils and mixtures thereof, and/or selected from the group consisting of secondary alkanesulfonate sodium salts, diphenyl oxide disulfonic acids and ether sulfates or mixtures thereof. The texturing composition may additionally comprise hydrofluoric acid in combination with any one or a mixture of any of the anionic surfactants described in this application and with or without nitric acid and/or any other acid.

In another aspect of the invention, the one or more sulfur-containing surfactants used in any texturing composition may have the following structure:

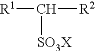

where R¹ and R² are independently straight chain or cyclic alkyl groups or phenyl groups or combinations, typically comprising 1-20 carbons and X is hydrogen or any cation, including Na, K, tetramethyl ammonium, tetraethyl ammonium, triethanol amine, or ammonium. Further in another aspect of the invention, with any of the components and compositions described herein, the texturing composition may comprise one or more acids selected from the group consisting of phosphoric acid, sulfuric acid or a water-soluble carboxylic acid, for example acetic acid, propionic acid, butyric acid, valeric acid, caproic acid, tartaric acid, succinic acid, adipic acid, propane-tricarboxylic acid and an isomer of propane-tricarboxylic acid.

In another aspect of the invention, the texturing composition, comprises any of the components described herein (alone or in combination with other components) in the amounts as follows: (1) from about 37 to about 42 wt % of HF, from about 3.5 to about 7 wt % of HNO3, from about 0.005 to about 0.25 wt % of surfactant, and the balance is water; (2) from about 24 to about 30 wt % of HF, from about 14 to about 19 wt % of HNO3, from about 0.005 to about 0.25 wt % surfactant and the balance is water, and (3) from about 9 to about 13 wt % of HF, from about 31 to about 39 wt % HNO3, from about 0.005 to about 0.25 wt % surfactant, and the balance is water.

The invention further provides a method of texturing a silicon wafer comprising, consisting essentially of or consisting of one or more steps including the step of wetting said wafer with a texturing composition comprising one or more acids, one or more anionic sulfur-containing surfactants, and water. The texturing composition useful in that method is any of the ones described above or herein with the components of the texturing composition used in any combination and amounts and optionally with other components. The method steps may further comprise first and second texturing steps with first and second texturing compositions wherein the second texturing composition may comprise one or more bases in solvent, with or without additional rinsing and/or drying steps before and/or the texturing steps. The method may further comprise pre-treatment and/or purification of the surfactant steps.

### BRIEF DESCRIPTION OF SEVERAL VIEWS OF THE DRAWINGS

FIG. 1 depicts a process flow diagram of a surface texturing process performed on a silicon substrate in accordance with one embodiment of the invention;

FIG. 2A depicts top-view images of a portion of a multicrystalline substrate prior to treatment by the process of this invention. The top-view images were taken using an Hitachi S-4700 FE (field emission) scanning electron microscopy (SEM) on a multicrystalline substrate surface at magnifications of 2K (top photograph) and 100K (bottom photograph);

FIG. 2B depicts top-view images of a portion of a multicrystalline substrate after the first texturing step using texturing composition Example F (Ex F), rinsing and drying the substrate in the process of this invention; the images were taken using the same SEM and magnification levels as described for FIG. 2A; and

FIG. 2C depicts top-view images of the multicrystalline substrate shown in FIG. 2B after further treatment of the substrate with the following steps: performing a second texturing step using a 0.5% KOH aqueous solution at ambient temperature for 1 min, rinsing with DI water and drying; the images were taken using the same SEM and magnification levels as described for FIG. 2A.

It is to be noted, that the appended drawings illustrate only exemplary embodiments of this invention and are therefore not to be considered limiting of its scope, for the invention may admit to other equally effective embodiments.

### DETAILED DESCRIPTION OF THE INVENTION

Crystalline silicon wafers (also referred to herein as substrates) are used to make solar cells, also referred to as photovoltaic cells, photoelectric cells or photo-cells, that are used to transform light into electricity. For this purpose it is desirable to generate texture on the surface of crystalline silicon wafers for photovoltaic uses. The texture reduces the reflectivity of the surface and allows more light to be converted to electricity thereby increasing the efficiency of the wafer.

When processing wafers using the composition and method of this invention, the first step of steps may involve optional cleaning step(s) to remove any contamination of the cut wafers (cut from ingots), which may be directly followed by one or more texturing steps. The texturing process may comprise a multistep process, that is, a texturing process that comprises one or two or more steps. For a multi-step or two-step texturing process, the texturing process comprises contacting the wafer with a first texturing composition or solution comprising one or more acids in solution followed by a second texturing step comprising a second texturing composition or solution comprising one or more bases in an alkaline solution. Either process may comprise additional rinse steps before or after one or both (or more) texturing steps. The typical rinse composition is purified water, such as deionized DI water. Before or after any or each of the texturing steps and/or the rinse steps may be a drying step. The drying step may be performed by directing dry air, heated air or nitrogen at the wafer. Typically the one or more texturing compositions are aqueous solutions.

The first texturing solution is an acidic solution comprising, consisting essentially of or consisting of one or more acids, one or more surfactants and solvent. The acids in the first texturing solution may comprise hydrofluoric acid (HF), and/or nitric acid (HNO3) and may also optionally comprise one or more additional acids sometimes referred to as adjusting agents. The adjusting agents include phosphoric acid, sulfuric acid or a water-soluble carboxylic acid, for example acetic acid, propionic acid, butyric acid, valeric acid, caproic acid, tartaric acid, succinic acid, adipic acid, propane-tricarboxylic acid and an isomer of propane-tricarboxylic acid for adjusting the etching rate of the texturing solution. If one or more adjusting agents are present, typically the texturing solution comprises from about 0 to 40 wt % of adjusting agent; however more or less of the adjusting agent may be used in alternative embodiments. The first texturing solution may comprise hydrofluoric acid, nitric acid, surfactant and solvent. Typically the acidic texturing solution may have a concentration from about 5 weight percent (wt %) to about 70 wt % of one or more acid or mixtures of acids (not including the adjusting agents) in solvent. The solvent may be deionized water (DI) or purified water. The first texturing solution may comprise one or more anionic surfactants.

Examples of some of the first texturing solutions that are the acidic texturing solutions of this invention useful in the method of this invention comprise, consist essentially of and consist of: (1) from about 37 to about 42 wt % of HF, from about 3.5 to about 7 wt % of HNO3, from about 0.005 to about 0.25 wt % of surfactant, and the balance is water (e.g. DIW), for example, in one embodiment from about 50.75 to about 59.495 wt % water; or (2) from about 24 to about 30 wt % of HF, from about 14 to about 19 wt % of HNO3, from about 0.005 to about 0.25 wt % surfactant and the balance is water (e.g. DIW), for example, in one embodiment from about 50.75 to about 61.995 wt % water; or (3) from about 9 to about 13 wt % of HF, from about 31 to about 39 wt % HNO3, from about 0.005 to about 0.25 wt % surfactant, and the balance is water (e.g. DIW), for example, in one embodiment from about 47.75 to about 59.995 wt % water; or (4) from about 75 to about 85 wt % of a 49 wt % solution of HF in DI water , from about 5 to about 10 wt % of a 70 wt % solution of HNO3 in DI water, and from about 0.005 to about 0.25 wt % of surfactant, and the balance DIW; or (5) from about 50 to about 60 wt % of a 49 wt % solution of HF in DI water, from about 20 to about 26 wt % of a 70 wt % solution of HNO3 in DI water, from about 0.005 to about 0.25 wt % surfactant, and the balance is DIW; or (6) from about 20 to about 25 wt % of a 49 wt % solution of HF in DI water, from about 45 to about 55 wt % a 70 wt % solution HNO3 in DI water and from about 0.005 to about 0.25 wt % surfactant, and the balance is DIW.

In one embodiment, the first texturing solutions that are the acidic texturing solutions of this invention useful in the method of this invention comprise, consist essentially of and consist of: from about 25 to about 27 wt % of HF, from about 15 to about 17 wt % of HNO3, from about 0.05 to about 0.25 wt % of surfactant, and the balance is water (e.g. DIW), for example, in one embodiment from about 55.75 to about 59.995 wt % water; or from about 53 to about 55 wt % of a 49 wt % solution of HF in DI water, from about 22 to about 24 wt % of a 70 wt % solution of HNO3 in DI water, and from about 0.05 to about 0.25 wt % of surfactant, and the balance DIW.

The acidic texturing compositions may comprise one or more anionic surfactants, including sulfur-containing anionic surfactants. Examples of anionic surfactants and sulfur-containing anionic surfactants useful in the texturing compositions of this invention include linear alkylbenzenesulfonates (LAS), straight chain fatty acids and/or salts thereof, coconut oil fatty acid derivatives, tall oil acid derivatives, sarcosides, acetylated polypeptides, secondary alkylbenzenesulfonate, lignin sulfonates, N-acyl-N-alkyltaurates, fatty alcohol sulfates (FAS), petroleum sulfonates, secondary alkanesulfonates (SAS), paraffin sulfonates, fatty alcohol ether sulfates (FAES), α-Olefin sulfonates, sulfosuccinate esters, alkylnapthalenesulfonates, isethionates, sulfuric acid esters, sulfated linear primary alcohols, sulfated polyoxyethylenated straight chain alcohols, sulfated triglyceride oils, phosphoric and polyphosphoric acid esters and perfluorinated anionics and mixtures thereof of these and any of the surfactants disclosed herein and other known surfactants. The texturing compositions may comprise α-olefin sulfonates having the following structure:

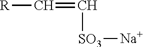

wherein R is an alkyl group, for example, a straight-chain alkyl group, having between from 10 to 18 carbons.

The surfactant used in the composition of this invention may be one or more of a sulfur-containing anionic surfactant with a sulfate or a sulfonate and may be a secondary alkanesulfonate surfactant or an alkyl sulfate surfactant or mixtures thereof. The surfactants may be used in free acid form as well as salt form. The surfactant having a sulfonate group may have the following structure:

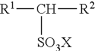

where R¹ and R² are independently straight chain or cyclic alkyl groups or phenyl groups or combinations, typically comprising 1-20 carbons and X is hydrogen or any cation, including Na, K, tetramethyl ammonium, tetraethyl ammonium, triethanol amine, or ammonium. In some embodiments the sulfonic surfactants comprise straight chain alkyl groups.

On particular example of the surfactant is Hostapur® SAS surfactant commercially available from Clariant, comprising molecules having the following structure:

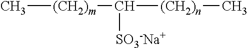

where m+n=10-14, the sulfonate group is distributed over the carbon chain in such a way that it is mainly the secondary carbon atoms that are substituted.

Further, the surfactant used in the composition of this invention may be fatty alcohol sulfates, which are derived from sulfonation of fatty alcohols with carbon chain length ranging from 8 to 22 atoms. An example of surfactant useful in the texturing compositions of this invention is sodium lauryl sulfate with the molecular formula C₁₂H₂₅O.(C₂H₄O)₂.SO₃.Na. The carbon chain length may vary for commercially manufactured surfactants of this type from 10 carbon atoms to 18 carbon atoms. The surfactant may also contain distributions of various carbon chain length surfactants.

Another example is sodium laureth sulfate having the following structure:

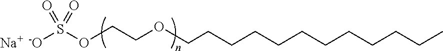

where “n” the number of ethoxylate groups in the surfactant chain can vary from 1 to 5. The carbon chain length may vary for commercially manufactured surfactants of this type from 10 carbon atoms to 18 carbon atoms. The surfactant may also contain distributions of various carbon chain length surfactants.

Commercially available surfactants useful in the texturing compositions of this invention include: Hostapur® SAS is a secondary alkanesulfonate-sodium salt manufactured by Clariant Corporation; Calfax®DBA70 is C12 (branched) diphenyl oxide disulfonic acid manufactured by Pilot Chemical Company; AEROSOL®NPES-3030 P is an ether sulfate manufactured by CYTEC CANADA, Inc. The preferred acidic texturing compositions of this invention may comprise, consist essentially of and consist of one or more acids, water, and at least one surfactant selected from the group of Hostapur® SAS, Calfax®DBA70 (10%) and AEROSOL®NPES-3030 P or mixtures thereof or mixtures with other surfactants. The preferred surfactants are selected from the group consisting of secondary alkanesulfonates, diphenyl oxide disulfonic acids, and ether sulfates.

Any of the surfactants or mixtures of surfactants may be used in any amounts or at concentrations from about 0.001 wt % to about 5 wt %, or from about 0.005 wt % to about 4 wt %, or from about 0.005 wt % to about 0.25 wt %. Note that the weight percentages (wt %), like all of the wt % herein, are based on the total weight of the texturing solution, unless otherwise stated herein. Useful surfactants may be purified using suitable techniques to remove metallic impurities. Purifying the surfactant may be one of the first steps performed when preparing the texturing composition of this invention. One useful purification technique is performing an ion exchange of the surfactant.

The second texturing composition may be an alkaline etching composition. Examples of alkaline etching compositions include those comprising, consisting essentially of and consisting of one or more bases, for example, one or more hydroxides in solvent. The one or more bases may be selected from the group of potassium hydroxide (KOH), sodium hydroxide (NaOH), ammonia (NH₄OH), tetramethylammonium hydroxide (TMAH; or (CH₃)₄NOH), or other similar basic components in a solvent, typically in water, deionized water (DIW) or otherwise purified water. The alkaline solution may have a concentration from about 0.1 wt % to about 15 wt %, or from about 0.5 wt % to about 10 wt %, or from about 0.5 wt % to about 5 wt % of one or more bases in deionized water (DI) water or other solvent.

In the texturing process comprising the first and second texturing steps using first and second texturing compositions respectively, it is believed (although not wishing to be bound by theory) that when the first texturing composition comprises, for example, an HF/HNO₃ etching composition, that the silicon is oxidized by the HNO₃ followed by dissolution of formed SiO₂ by HF. The process of acidic texturing with a composition comprising HF and HNO3 is an exothermic reaction that simultaneously produces a nanoporous layer on Si surface. This nanoporous layer is unfavorable for solar cells manufacturing due to its high resistivity, high light absorption and recombination of hole-electrons in this layer. In some embodiments of the method of this invention, it is subsequently removed in the dilute alkaline solution in the second texturing step using the second texturing composition. Therefore, for some embodiments using the texturing process having the two texturing steps, the crystalline silicon surface texturing involves both acidic etching (the first texturing step) and an alkaline nanopore removal step (the second texturing step). The acidic etching process contributes to the resulting surface morphology and total Si loss, which are critical factors in determining texturing quality. As the acidic etching process is isotropic, Si etches occur preferentially at defects and/or grain boundaries and independent of crystal orientation. When the Si loss is too low i.e. less than about 2 μm, the Si surface is covered by micro-cracks of the damaged layer. This is unfavorable for solar cells manufacturing. When the Si loss is too high, i.e over about 8 μm, the texturing disappears, and the dislocation and grain boundaries appear. This leads to higher surface reflectivity and can mechanical weaken the wafers. The acidic texturing composition of this invention provides acceptable Si loss, that is, from about 2 to about 8 μm or from about 3 to about 6 μm or from about 4 to about 5 μm using the method of this invention.

The first or second (acidic or alkaline) texturing compositions may also comprise one or more additives to promote cleaning and/or texturing (etching) of the wafer surface. Cleaning additives may help remove debris remaining on the surface. Optionally the first or second or other texturing compositions of this invention may comprise one or more additional components (additives) including inorganic or organic acids and their salts, bases and their salts, chelating agents, defoaming agents, wetting agents and/or etching agents or mixtures thereof. In some embodiments the texturing compositions of this invention are free of or substantially free (“substantially free” means less than 0.001 wt % any where it is used except if otherwise defined herein) of any one or all of the following: acids and their salts, bases and their salts, chelating agents, dispersants, defoaming agents, wetting agents, and/or etching agents described herein.

The first or second texturing compositions, typically the first, may further comprise inorganic acids including hydrochloric acid, sulfuric acid, phosphoric acid, sulfamic acid, etc. A mixture of these acids and/or their salts may be used as well. The texturing composition of this invention may further comprise organic acids and/or their salts. Organic acids can be chosen from a broad range of acids, including but not limited to: acetic acid, oxalic acid, citric acid, maliec acid, malic acid, malonic acid, gluconic acid, glutaric acid, ascorbic acid, formic acid, ethylene diamine tetraacetic acid, diethylene triamine pentaacetic acid, glycine, alanine, cystine, sulfonic acid, various derivatives of sulfonic acid, etc or mixtures thereof. Salts of these acids may also be used. A mixture of these acids/salts may be used as well. The texturing composition of this invention may contain acids and/or salts of those acids in any amount or in amounts ranging from 0 to 20 wt % or from 0 to 5 wt % or from 0 to1 wt %.

The first or second texturing compositions, typically the second may further comprise one or more bases. The base may be selected from a range of chemicals, including but not limited to: ammonium hydroxide, potassium hydroxide, a quaternary ammonium hydroxide, an amine, guanidiene carbonate, and organic bases. The bases may be used either alone or in combination with other bases. Examples of suitable organic bases include, but are not limited to: hydroxylamines, organic amines such as primary, secondary or tertiary aliphatic amines, alicyclic amines, aromatic amines and heterocyclic amines, aqueous ammonia, and quaternary ammonium hydroxides. Specific examples of the hydroxylamines include: hydroxylamine (NH₂OH), N-methylhydroxylamine, N,N-dimethylhydroxylamine and N,N-diethylhydroxylamine. Specific examples of the primary aliphatic amines include: monoethanolamine, ethylenediamine and isopropanolamine. Specific examples of the secondary aliphatic amines include: diethanolamine, N-methylaminoethanol, dipropylamine and 2-ethylaminoethanol and 2-(2-aminoethylamino)ethanol. Specific examples of the tertiary aliphatic amines include: triethanolamine, dimethylaminoethanol and ethyldiethanolamine. Specific examples of the alicyclic amines include: cyclohexylamine and dicyclohexylamine. Specific examples of the aromatic amines include: benzylamine, dibenzylamine and N-methylbenzylamine. Specific examples of the heterocyclic amines include: pyrrole, pyrrolidine, pyrrolidone, pyridine, morpholine, pyrazine, piperidine, N-hydroxyethylpiperidine, oxazole and thiazole. Specific examples of quaternary ammonium salts include: tetramethylammonium hydroxide (TMAH), tetraethylammonium hydroxide, tetrapropylammonium hydroxide, trimethylethylammonium hydroxide, (2-hydroxyethyl)trimethylammonium hydroxide, (2-hydroxyethyl)triethylammonium hydroxide, (2-hydroxyethyl)tripropylammonium hydroxide and (1-hydroxypropyl)trimethylammonium hydroxide. The texturing composition of this invention may further contain bases and/or salts of those bases in any amount or in amounts ranging from 0 to 20 wt % or from 0 to 5 wt % or from 0 to 1 wt %. The first and/or second texturing compositions of this invention may further comprise one or more chelating agents. The chelating agents may be selected from, but not limited to: ethylenediaminetetracetic acid (EDTA), N-hydroxyethylethylenediaminetriacetic acid (NHEDTA), nitrilotriacetic acid (NTA), diethylenetriaminepentaceticdiethylenetriaminepentaacetic acid (DPTA), ethanoldiglycinate, citric acid, gluconic acid, oxalic acid, phosphoric acid, tartaric acid, methyldiphosphonic acid, aminotrismethylenephosphonic acid, ethylidene-diphosphonic acid, 1-hydroxyethylidene-1,1-diphosphonic acid, 1-hydroxypropylidene-1,1-diphosphonic acid, ethylaminobismethylenephosphonic acid, dodecylaminobismethylenephosphonic acid, nitrilotrismethylenephosphonic acid, ethylenediaminebismethylenephosphonic acid, ethylenediaminetetrakismethylenephosphonic acid, hexadiaminetetrakismethylenephosphonic acid, diethylenetriaminepentamethylenephosphonic acid and 1,2-propanediaminetetetamethylenephosphonic acid or ammonium salts, organic amine salts, maronic acid, succinic acid, dimercapto succinic acid, glutaric acid, maleic acid, phthalic acid, fumaric acid, polycarboxylic acids such as tricarbaryl acid, propane-1,1,2,3-tetracarboxylic acid, butane-1,2,3,4-tetracarboxylic acid, pyromellitic acid, oxycarboxylic acids such as glycolic acid, B-hydroxypropionic acid, citric acid, malic acid, tartaric acid, pyruvic acid, diglycol acid, salicylic acid, gallic acid, polyphenols such as catechol, pyrogallol, phosphoric acids such as pyrophosphoric acid, polyphosphoric acid, heterocyclic compounds such as 8-oxyquinoline, and diketones such as α-dipyridyl acetylacetone. The texturing compositions of this invention may contain chelating agents in any amounts or concentrations ranging from 0 wt % to 10 wt % or 0.0001 to 10 wt %.

The first and/or second texturing compositions may further comprise one or more defoaming agents. The defoaming agents may be selected from, but not limited to: silicones, organic phosphates, ethylene oxide/propylene oxide (EO/PO) based defoamers containing polyethylene glycol and polypropylene glycol copolymers, alcohols, white oils or vegetable oils and the waxes are long chain fatty alcohol, fatty acid soaps or esters. The texturing compositions may contain defoaming agents in any amount or in an amount ranging from about 0.0001 wt % to about 5 wt % or from about 0.001 wt % to about 1 wt %. Some compositions, such as some silicone surfactants may function as both defoaming agent and surfactant. The first texturing compositions may contain oxidizing agents such as nitric acid, peroxides, nitrates, nitrites, hypochlorites, perchlorates, persulfates, permanganates, peroxysulfuric acid and sulfuric acid in concentrations ranging from 0 to 99 wt % or from 0 to 50 wt %.

The total weight percent of additives in the texturing compositions of this invention should be less than 10 wt % or be less than 5 wt % or should be from 0 to 10 wt % or 0 to 5 wt %.

The texturing composition of this invention and the method of this invention may be used to texture a wafer that may be a monocrystalline substrate (e.g., Si<100> or Si<111>), a microcrystalline silicon substrate, a strained silicon substrate, an amorphous silicon substrate, a doped or undoped polysilicon, polycrystalline (or multicrystalline) substrate, glass, sapphire or any type of silicon containing substrate. Typically the method and composition of this invention are used on multicrystalline silicon substrates. The first texturing step that may precede the second texturing step (in embodiments of the invention having first texturing and second texturing steps) is a texturing step that involves the use of a composition of this invention comprising, consisting essentially of and consisting of at least one acid or mixtures of more than one acid, a surfactant or mixtures of more than one surfactant and a solvent or mixtures of solvent. In some embodiments, the first texturing step is followed by a second texturing step comprising an alkaline second texturing composition.

The wafers are wetted by the first and/or second and/or other texturing compositions in the texturing method of this invention. The wafers may be wetted by flooding, spraying, immersing, or other suitable manner. In some cases, agitation of the first and/or second texturing composition is needed to assure that the composition is always in intimate contact with the surface of the substrate during the texturing process.

Typically the process is a multi-step texturing process having multiple (for example two) texturing steps; however, this invention contemplates a texturing composition and process involving the first texturing step only. The texturing process may comprise one or more rinse steps, one or more cleaning steps and/or other steps in addition to the one or multiple texturing steps. The wafer may be wetted with the first texturing composition of this invention after an optional cleaning step. Additionally the wafer may be wetted with the second texturing composition immediately after the first texturing step or after other optional steps. Presently using the first and second texturing compositions as the texturing steps appears to be the most effective in terms of improving the surface reflectance for multicrystalline wafers.

The wafers may be rinsed in separate rinsing steps before and after the one or more texturing steps. The wetting may be done at room temperature or sub-ambient temperature, for example from 0° C. to 40° C. or 5 to 25° C. for any of the steps. The wafer may be wetted with the texturing compositions for a time that may vary based on the method by which the first and/or second texturing composition is applied to the wafer. Typically, a single wafer processing on a conveyor belt through the texturing process may have much smaller treatment time compared to a batch scale immersion texturing process. The steps could each be in the range of 1 second to an hour. Preferred texturing step times may be between 20 seconds and 30 minutes. The times for each of the texturing steps may be reduced by increasing the temperature of the texturing bath.

The second texturing composition may or may not intentionally comprise a surfactant, that is, it may be substantially free of surfactant. Substantially free of surfactant means less than 0.001 wt % of surfactant. The second texturing composition may be surfactant-free when it is formulated; however, some surfactant may be introduced to the texturing bath from the wafer when the wafer with residual surfactant thereon from the first texturing step of this invention is wetted with the second texturing composition.

Some methods of this invention comprise, consist essentially of and consist of the following steps: wetting the wafer with the first texturing composition; wetting the wafer with the second texturing composition; rinsing with DIW and drying the wafer. Other methods of this invention comprise, consist essentially of and consist of the following steps: wetting the wafer with the first texturing composition for from about 1 to about 5 minutes at from about 7 to 15° C.; rinsing with DIW; and wetting the wafer with the second texturing composition for from about 5 sec to about 5 minutes at ambient temperature; rinsing with DIW and drying the wafer.

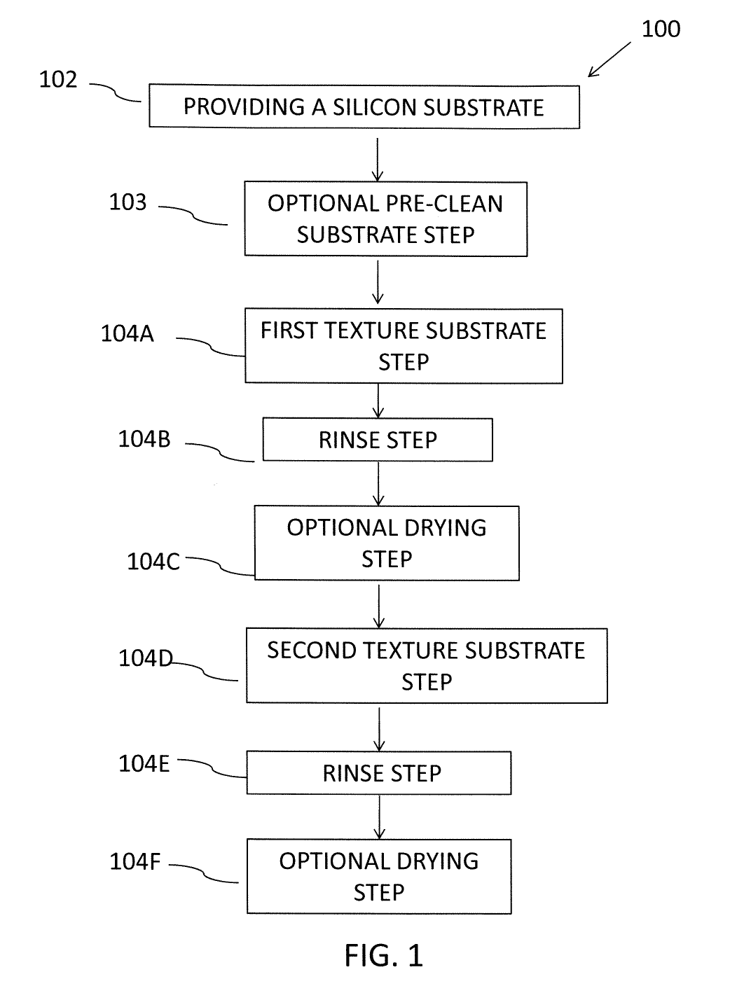

FIG. 1 depicts a flow diagram of one embodiment of a surface texturing process sequence 100 suitable for performing on a silicon substrate. Although the process sequence 100 is illustrated for solar cell manufacturing process, the process sequence 100 may be beneficially utilized to form textured surfaces suitable for other structures and applications. In one embodiment, the process sequence 100 discussed below is performed in an automated production line that has a robotic device that is adapted to transfer each of the processed substrates to a series of processing baths that are adapted to perform all of the processing steps discussed below. While not shown in FIG. 1, alternative embodiments of the process sequence 100 may include additional steps, for examples, drying steps and/or additional rinsing steps between each of the processing steps discussed below. The additional rinsing steps may prevent over exposure to the processing chemistry during each step and reduce the chance of cross-contamination, for example due to chemical carryover, between adjacent processing baths. In the embodiment shown in FIG. 1, the texturing process comprises a first texturing step 104A and second texturing step 104D; however, although not shown, it is understood that more than two texturing steps using the same or alternative texturing compositions may be used to texture a substrate. The steps of the invention described below may include means to agitate the compositions used in each step.

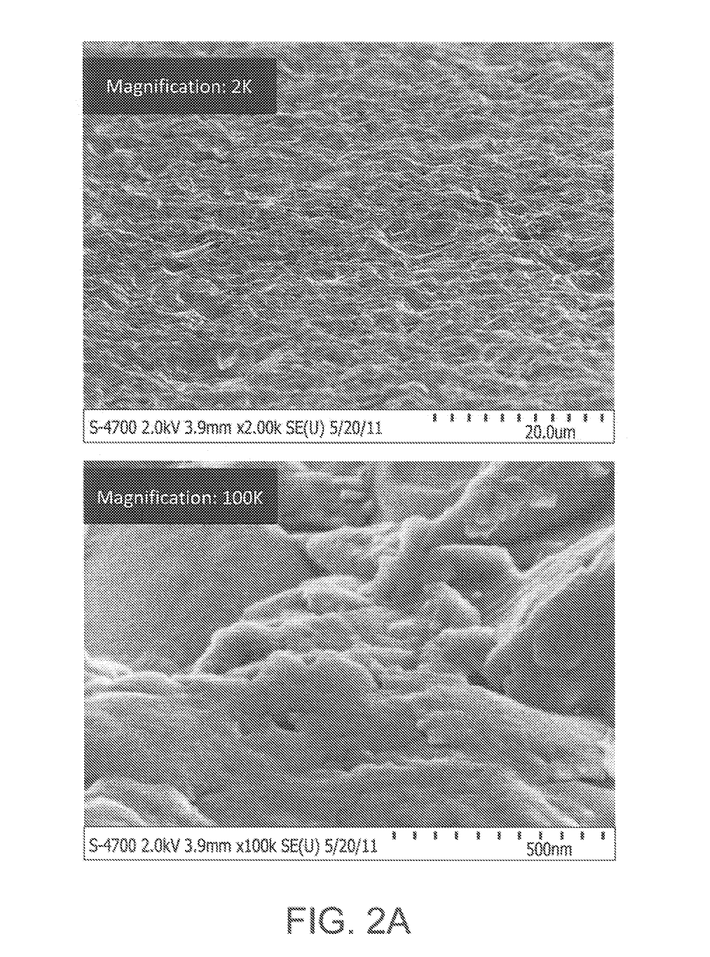

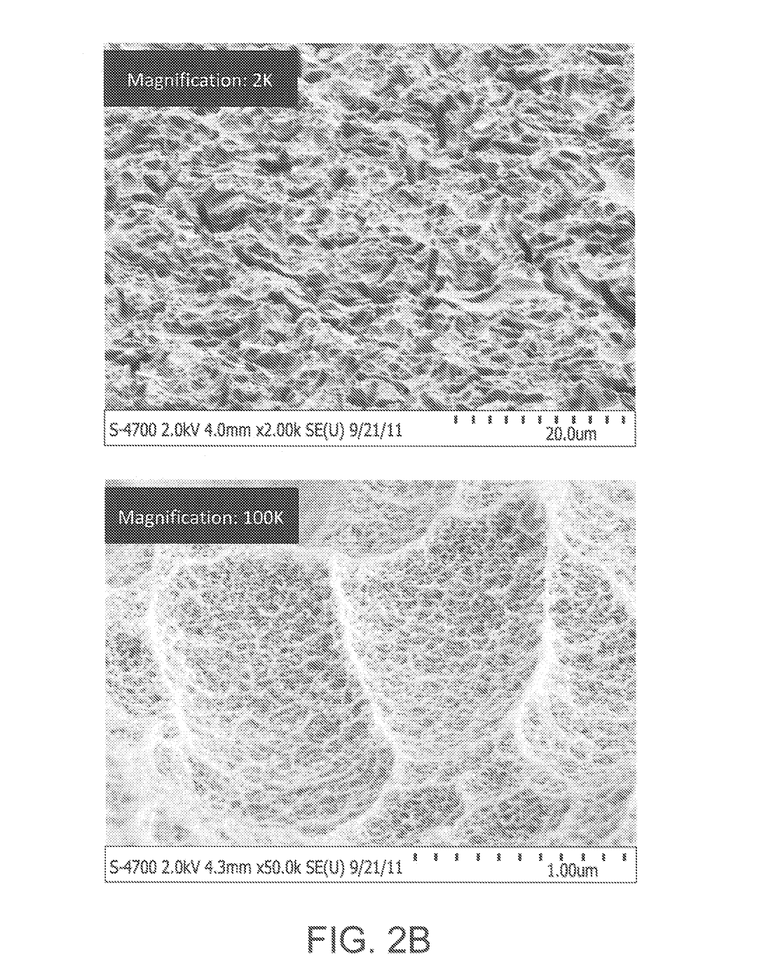

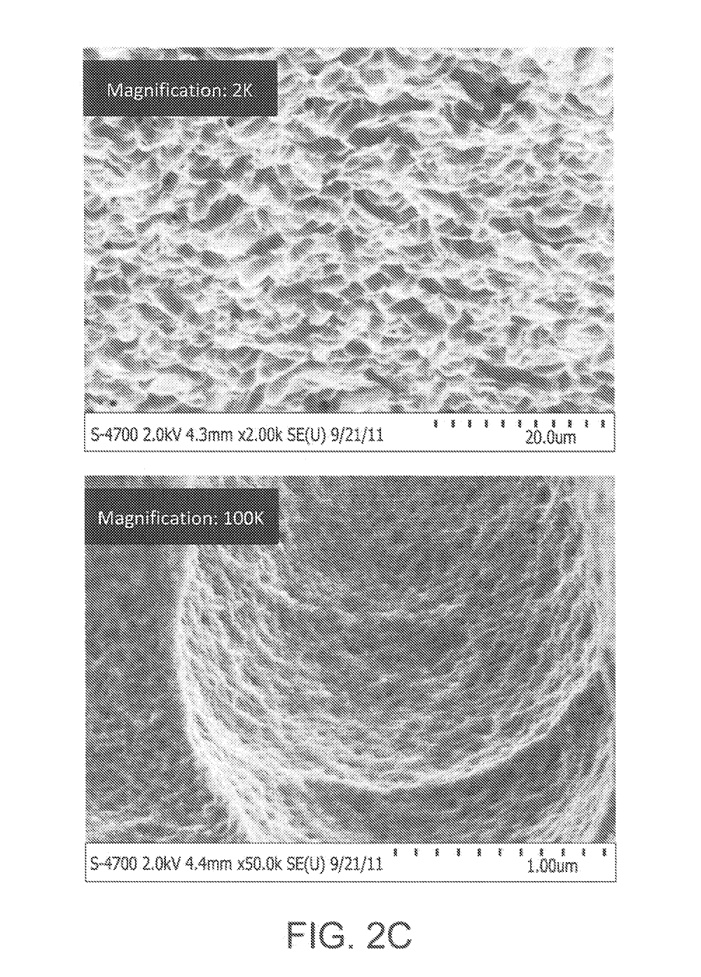

The process sequence 100 begins at step 102 by providing a silicon substrate. The substrate may have a thickness between about 100 μm and about 400 μm. In one embodiment, the substrate may be a monocrystalline substrate (e.g., Si<100> or Si<111>), a microcrystalline silicon substrate, a polycrystalline (multicrystalline) silicon substrate, a strained silicon substrate, an amorphous silicon substrate, a doped or undoped polycrystalline silicon substrate, glass, sapphire or any type of silicon containing substrate. In the embodiment wherein the substrate is desired to be an n-type crystalline silicon substrate, donor type atoms are doped within the crystalline silicon substrate during the substrate formation process. Suitable examples of donor atoms include, but not limited to, phosphorus (P), arsenic (As), antimony (Sb). Alternatively, in the embodiment wherein a p-type crystalline silicon substrate is desired, acceptor type atoms may be doped into the crystalline silicon substrate during the substrate formation process. FIG. 2A shows top-views of the portion of multicrystalline substrate prior to texturing processes. The surface reflectance of the untextured substrate is 36.5%.

At step 103 the substrate is optionally pre-cleaned prior to performing the texturing process (e.g., steps 104A-F). In alternative embodiments (not shown), the pre-clean process is a multi-step process that is used to remove unwanted contamination, surface damage and/or other materials that could affect the subsequent processing steps. In one embodiment, in step 103, the pre-clean process may be performed by wetting the substrate with an acid solution and/or solvent to remove surface particles, native oxide or other contaminants from the substrate. The pre-clean solution may be a hydrofluoric acid (HF) aqueous solution having a mixture of hydrofluoric acid and deionized water at a ratio between about 0.1:100 to about 4:100. In one embodiment, the pre-clean solution may be a hydrofluoric acid (HF) aqueous solution having a concentration between about 0.1 weight percent and about 4 weight percent, such as between about 1 weight percent and about 2 weight percent HF and the balance is deionized water. The pre-cleaning solution may comprise ozonated DI water having between about 1 ppm-30 ppm of ozone disposed in DI water. The pre-clean process may be performed on the substrate between about 5 seconds and about 600 seconds, such as about 30 seconds to about 240 second, for example about 120 seconds. The pre-clean solution may also be a standard cleaning solution SC1, a standard cleaning solution SC2, or other suitable and cost effective cleaning solution may be used to clean a silicon containing substrate. (SC1 consists of NH₄OH (28%), H₂O₂ (30%) and deionized water, the classic formulation is 1:1:5, typically used at 70° C.; however, it may comprise a higher ratio of water. SC2 consists of HCl (73%), H₂O₂ (30%) and deionized water, originally developed at a ratio of 1:1:5, typically used at 70° C.; however, it may comprise a higher ratio of water). In one example, the pre-clean process includes immersing the substrate in an aqueous solution comprising 2% by volume hydrofluoric acid (HF), at room temperature for a time of between about 1 to 3 minutes. At step 104A, the first step of the texturing process, the substrate is wetted by the texturing composition of this invention comprising surfactant. The substrate may be wetted by flooding, spraying, immersion, or other suitable manner. The wetting may take place in a bath, an in-line tool or beaker. Examples of suitable first texturing compositions were described above and include those disclosed in the examples below. The wetting may be done at sub-ambient or room temperature, for example from 0° C. to 25° C. or 5 to 15° C. or 6 to 8° C. The time for wetting will vary with the various methods and in the case of a texturing bath may vary for a single wafer as opposed to batch scale immersion method. The treatment time could be in the range of 1 second to 1 hour. Preferred treatment times for the first texturing step may be between 20 seconds and 30 minutes, 30 second to 15 minutes or 1 minute to 5 minutes.

The surface of the wafer after the first texturing step is typically etched by the first texturing composition, that is, the saw damaged Si layer is removed and the surface of the wafer is covered with oval shaped pits and nanopores. After the first texturing step 104A shown in FIG. 1 is a preferred rinse step 104B. The rinse step typically comprises wetting the substrate with water or DI water and may comprise immersion of the substrate in a bath of water or DI water for 10 minutes or less or 5 minutes or less.

After rinse step 104B, an optional drying step 104C may be performed to remove water, some, most or substantially all of the texturing composition and any other residual chemicals from the substrate surface. The drying process may include drying the substrate with a flow of nitrogen gas, or a flow of clean dry air or heated air or nitrogen for 1 to 60 minutes. FIG. 2B shows top-views of the multicrystalline substrate surface after step 104C. The surface is covered by uniform pits and nanopores and surface reflectance is 16.7%.

At step 104D, in the embodiment shown in FIG. 1, the substrate after steps 104A-C is wetted by a second texturing composition to remove the nanopores from the surface. The second texturing (etching) solution may be any composition that is effective at texturing the substrate surface, including any known texturing solutions. In one embodiment, the texturing composition is an alkaline solution that may have one or more other additives therein and is maintained at a temperature from about 0° C. to about 95° C. or from 10° C. to 50° C. or ambient temperature. In another embodiment, the alkaline solution for texturing (etching) the silicon substrate may be an aqueous solution comprising one or more of the following: potassium hydroxide (KOH), sodium hydroxide (NaOH), ammonia (NH₄OH), tetramethylammonium hydroxide (TMAH or (CH₃)₄NOH), or other similar base. The alkaline solution may have a concentration between from about 0.1 weight % to about 15 weight % of KOH (or other base or mixture of bases) in deionized water (DI) water, or from about 0.25 weight % to about 10 weight % of KOH (or other base or mixture of bases) in deionized water (DI) water, or from about 0.5 weight % to about 5 weight % of KOH (or other base or mixture of bases) in deionized water (DI) water.

After the second texturing step 104D is complete, there may be performed a preferred rinse step 104E, for example, a water rinse step as described above and/or an optional drying step 104F may be performed to remove some, most or substantially all of the texturing composition and any other residual chemicals from the substrate surface. The drying process may include drying the substrate with a flow of nitrogen gas, or a flow of clean dry air or heated air or nitrogen for 1 to 60 minutes. FIG. 2C shows top-views of the multicrystalline substrate surface after step 104F. The surface is covered by uniform pits without nanopores and surface reflectance is 22.9%.

After the texturing process is performed on the substrate surface, the substrate reflectance is typically decreased to 30% or less, or to 26% or less, or to 23% or less, using the method of measuring the reflectivity described below.

The following examples illustrate the texturing compositions and methods of this invention.

### EXAMPLES

Pieces were clamped horizontally in the beaker using a fixture. Unless otherwise indicated, rinsing was performed by overflow rinse using a DI water flow rate of approximately 100 milliliters per minute (ml/min). If a temperature is not specified for a step, the temperature was room temperature. If only part of a composition is specified herein, the balance was DI water. The silicon loss was measured in the first texturing step by measuring the weight change of the wafer piece just before and after the texturing step and calculating the total silicon loss based on total thickness of the untextured wafer multiplied by the weight percent change. Wafer reflectivity measurements are made on the Perkin-Elmer Lambda 900 UVNIS/NIR Spectrometer. The instrument was fitted with an integrating sphere to capture the reflected radiation.

### Example 1

In this example, mono and multi-crystalline wafers (identified in the tables below were treated by a 2-step texturing process (with additional rinse and drying steps; however there were no saw damage nor other pre-treatment steps, e.g. no pre-clean steps)). The first texturing step entailed wetting by horizontally submerging each wafer into the first texturing composition identified in the tables below (Tables 1, 1A, 2, 2A, 3, 3A, 4, 4A, 5, 6 and 6A) for from about 1-3 min at 7-10° C., and then rinsing with deionized water (DIW) and nitrogen drying, followed by the second texturing step, of wetting by vertically submerging each treated wafer into a 0.5% to 5% by weight KOH aqueous solution (for nanopore removal) for 10 sec to 1 min at ambient temperature, and then rinsing each wafer with DIW and nitrogen drying the wafer. Silicon loses on both sides were determined based on weight changes. Reflectance was measured on each of the wafers, on the side of the wafer facing the bottom of the beaker, using a Perkin-Elmer Lambda 900 spectrophotometer equipped with an integrating sphere. Average-weighted reflectance (“WAR”) was calculated by integrating the reflectivity losses under AM1.5 standard solar illumination from 400 to 1100 nm.

TABLE 1

| | | | | Si | *WAR | |
|---|---|---|---|---|---|---|
| Texturing | surfactant | T | Time | loss | 400-1100 | wafer |
| compositions | wt % neat | (° C.) | (min) | μm | nm % | types |
| Comparative | 0 | 7-8 | 1 | 3.99 | 32.76% | multi-Si |
| Ex I | | | | | | |
| Ex A | 0.025 | 7-8 | 2 | 5.62 | 25.15% | multi-Si |
| | | 7-8 | 2 | 5.67 | 23.74% | mono-Si |
| Ex B | 0.035 | 7-8 | 2 | 5.24 | 23.97% | multi-Si |
| Ex C | 0.040 | 7-8 | 2 | 4.90 | 25.31% | multi-Si |
| | | 7-8 | 2 | 4.52 | 25.58% | mono-Si |
| Ex D | 0.050 | 7-8 | 3 | 6.94 | 24.20% | multi-Si |

*Average-weighted reflectances were measured after step 104F. (In the second texturing step, the nanopores were removed by wetting each wafer with a 0.5 weight % KOH aqueous solution at ambient temperature for 1 min.)

The texturing compositions used in the Comparative Examples and Examples shown in Table 1 are in Table 1A as follows:

TABLE 1A

| | Texturing Compositions listed in Table 1 | | | | |
|---|---|---|---|---|---|
| | Comparative | | | | |
| Components | Ex I | Ex A | Ex B | Ex C | Ex D |
| HF (49 wt % in DIW) | 81.56 | 81.56 | 81.56 | 81.56 | 81.56 |
| (wt %) | | | | | |
| HNO₃ (70 wt % in | 6.62 | 6.62 | 6.62 | 6.62 | 6.62 |
| DIW) (wt %) | | | | | |
| DIW (wt %) | 11.82 | 11.57 | 11.47 | 11.42 | 11.32 |
| *Hostapur ® SAS (10 wt | 0 | 0.25 | 0.35 | 0.40 | 0.50 |
| % in DIW) (wt %) | | | | | |

*Hostapur ® SAS is a secondary alkanesulfonate-sodium salt manufactured by Clariant Corporation. It was purified before use by performing an ion exchange.

TABLE 2

| | | | | Si | *WAR | |
|---|---|---|---|---|---|---|
| Texturing | surfactant | T | Time | loss | 400-1100 | wafer |
| compositions | wt % neat | (° C.) | (min) | μm | nm % | types |
| Comparative | 0 | 7-8 | 1 | 5.42 | 29.57% | multi-Si |
| Ex II | | | | | | |
| Ex E | 0.010 | 7-8 | 2 | 6.19 | 25.32% | multi-Si |
| Ex F | 0.015 | 7-8 | 1.5 | 6.18 | 22.33% | mono-Si |
| | | 7-8 | 1.5 | 4.49 | 22.91% | multi-Si |
| Ex G | 0.020 | 7-8 | 1.5 | 4.95 | 22.49% | mono-Si |

*Average-weighted reflectances were measured after step 104F. (In the second texturing step, the nanopores were removed by wetting each wafer with a 0.5 weight % KOH aqueous solution at ambient temperature for 1 min.)

The texturing compositions used in the Comparative Examples and Examples shown in Table 2 are in Table 2A as follows:

TABLE 2A

| | Texturing Compositions Listed in Table 2 | | | |
|---|---|---|---|---|
| | Comparative | | | |
| Components | Ex II | Ex E | Ex F | Ex G |
| HF (49 wt % in DIW) | 54.00 | 54.00 | 54.00 | 54.00 |
| (wt %) | | | | |
| HNO3 (70% wt % in | 23.00 | 23.00 | 23.00 | 23.00 |
| DIW) (wt %) | | | | |
| DIW (wt %) | 23.00 | 22.90 | 22.85 | 22.80 |
| Hostapur ® SAS (10 wt | 0 | 0.10 | 0.15 | 0.20 |
| % in DIW) (wt %) | | | | |

TABLE 3

| | | | | Si | *WAR | |
|---|---|---|---|---|---|---|
| Texturing | surfactant | T | Time | loss | 400-1100 | wafer |
| compositions | wt % neat | (° C.) | (min) | μm | nm % | types |
| Comparative | 0 | 7-8 | 1 | 5.11 | 30.63% | multi-Si |
| Ex III | | | | | | |
| Ex H | 0.025 | 7-8 | 1.5 | 4.15 | 26.66% | multi-Si |
| | | 7-8 | 1.5 | 4.92 | 26.78% | multi-Si |
| Ex J | 0.035 | 7-8 | 2 | 4.43 | 25.65% | multi-Si |
| Ex K | 0.045 | 7-8 | 1.5 | 3.91 | 24.87% | multi-Si |
| | | 7-8 | 1.5 | 4.74 | 24.99% | multi-Si |

*Average-weighted reflectances were measured after step 104F. (In the second texturing step, the nanopores were removed by wetting each wafer with a 0.5 weight % KOH aqueous solution at ambient temperature for 1 min.)

The texturing compositions used in the Comparative Example and Examples shown in Table 3 are in Table 3A as follows:

TABLE 3A

| | Texturing Compositions Listed in Table 3 | | | |
|---|---|---|---|---|
| | Comparative | | | |
| Components | Ex III | Ex H | Ex J | Ex K |
| HF (49 wt % in DIW) | 22.60 | 22.60 | 22.60 | 22.60 |
| (wt %) | | | | |
| HNO3 (70 wt % in | 49.37 | 49.37 | 49.37 | 49.37 |
| DIW) (wt %) | | | | |
| DIW (wt %) | 28.03 | 27.78 | 27.68 | 27.58 |
| *Hostapur ® SAS (10 wt | 0 | 0.25 | 0.35 | 0.45 |
| % in DIW) (wt %) | | | | |

TABLE 4

| | | | | Si | *WAR | |
|---|---|---|---|---|---|---|
| Texturing | Surfactant | T | Time | loss | 400-1100 | wafer |
| compositions | wt % neat | (° C.) | (min) | μm | nm % | types |
| Comparative | 0 | 7-8 | 1.5 | 4.08 | 30.50% | multi-Si |
| Ex IV | | | | | | |
| Ex L | 0.001 | 7-8 | 1.5 | 4.78 | 32.31% | mono-Si |
| Ex M | 0.010 | 7-8 | 1.5 | 4.04 | 29.87% | mono-Si |
| | | 7-8 | 1.5 | 4.83 | 31.23% | multi-Si |
| Comparative | 0 | 7-8 | 0.5 | 2.55 | 30.41% | multi-Si |
| Ex V | | | | | | |
| Ex N | 0.10 | 7-8 | 2 | 4.18 | 33.64% | multi-Si |

*Average-weighted reflectances were measured after step 104F. (In the second texturing step, the nanopores were removed by wetting each wafer with a 0.5 weight % KOH aqueous solution at ambient temperature for 1 min.)

The texturing compositions used in the Comparative Example and Examples shown in Table 4 are in Table 4A as follows:

TABLE 4A

| | Texturing Compositions Listed in Table 4 | | | | |
|---|---|---|---|---|---|
| | Comparative | | | Comparative | |
| Components | Ex IV | Ex L | Ex M | Ex IV | Ex N |
| HF (49 wt % in DIW) | 14.5 | 14.5 | 14.5 | 15.74 | 17.83 |
| (wt %) | | | | | |
| HNO3 (70 wt % in | 56.2 | 56.2 | 56.2 | 38.32 | 37.98 |
| DIW) (wt %) | | | | | |
| Acetic Acid (wt %) | 0 | 0 | 0 | 45.94 | 43.19 |
| DIW (wt %) | 29.3 | 29.29 | 29.2 | 0 | 0 |
| Hostapur ® SAS | 0 | 0.01 | 0.10 | 0 | 1.00 |
| (10 wt % in DIW) | | | | | |
| (wt %) | | | | | |

### Example 2

Texturing composition Example F (Ex F) defined in Table 2A was used in the same 2 texturing steps process (with rinse and drying steps) as used in Example 1 and reported in Table 2 using different wafers from different wafer sources. The results are reported in Table 5.

TABLE 5

| Wafer | T | Time | Si loss | *WAR | |
|---|---|---|---|---|---|
| sources | (° C.) | (min) | μm | 400-1100 nm % | wafer types |
| Source 1 | 7-8 | 1.5 | 6.18 | 22.33% | mono-Si |
| | 7-8 | 1.5 | 4.49 | 22.91% | multi-Si |
| Source 2 | 7-8 | 1.5 | 6.02 | 23.41% | mono-Si |
| | 7-8 | 1.5 | 5.37 | 22.20% | multi-Si |
| Source 3 | 7-8 | 1.5 | 4.27 | 21.43% | multi-Si |
| Source 4 | 7-8 | 1.5 | 4.33 | 23.68% | multi-Si |
| Source 5 | 7-8 | 1.5 | 4.43 | 23.51% | multi-Si |

*As described for Example 1, average-weighted reflectances were measured after step 104 F. (after wetting each wafer with 0.5 wt % KOH aqueous texturing solution at ambient temperature for 1 min).

### Example 3

Additional texturing compositions were tested in the same process described in Example 1. The results are reported in Table 6 (Note, three earlier examples are repeated in Table 6). Compositional information can be found for Comparative Ex 1 and Ex A in Table 1A and Comparative Ex II and Ex F in Table 2A.)

TABLE 6

| Texturing | | T | Time | Si loss | *WAR 400- | wafer |
|---|---|---|---|---|---|---|
| Compositions | Surfactant | (° C.) | (min) | μm | 1100 nm % | types |
| Comparative | None | 7-8 | 1 | 3.99 | 32.76% | multi-Si |
| Ex I | | | | | | |
| Ex A | Hostapur ® SAS | 7-8 | 2 | 5.62 | 25.15% | multi-Si |
| | (10%) | | | | | |
| Ex O | **Calfax ®DBA70 (10%) | 7-8 | 2 | 5.47 | 25.24% | multi-Si |
| Ex P | ***AEROSOL ®NPES - | 7-8 | 2 | 4.80 | 22.09% | multi-Si |
| | 3030 P (30%) | | | | | |
| Comparative | None | 7-8 | 1 | 5.42 | 29.57% | multi-Si |
| Ex II | | | | | | |
| Ex F | Hostapur SAS (10%) | 7-8 | 1.5 | 6.18 | 22.33% | mono-Si |
| Ex Q | Calfax: DBA70 (10%) | 7-8 | 1.5 | 4.25 | 23.57% | multi-Si |

*As described for Example 1, average-weighted reflectance was measured after wetting each wafer with 0.5 wt % KOH aqueous texturing solution at ambient temperature for 1 min.
**Calfax ®DBA70 (10%) is C12 (branched) diphenyl oxide disulfonic acid manufactured by Pilot Chemical Company.
***AEROSOL ®NPES - 3030 P is an ether sulfate manufactured by CYTEC CANADA INC.

The texturing compositions of Examples O, P and Q in Table 6 are in Table 6A as follows:

TABLE 6A

| | Texturing Compositions | | |
|---|---|---|---|
| | Listed in Table 6 | | |
| Components | Ex O | Ex P | Ex Q |
| HF (49 wt % in DIW) | 81.56 | 81.56 | 54.00 |
| (wt %) | | | |
| HNO3 (70 wt % in | 6.62 | 6.62 | 23.00 |
| DIW) (wt %) | | | |
| DIW (wt %) | 11.57 | 11.74 | 22.85 |
| Calfax ® DBA70 (10 wt | 0.25 | 0 | 0.15 |
| % in DIW) (wt %) | | | |
| AEROSOL ® NPES - | 0 | 0.08 | 0 |
| 3030 P (30%) (wt %) | | | |

Although the invention has been described with reference to specific process steps and compositions useful in those process steps, including those used in the examples above, it will be apparent that other embodiments are possible and fall within the scope of the invention.

1. A texturing composition for texturing silicon wafers comprising one or more acids, one or more anionic sulfur-containing surfactants and water.

2. The texturing composition of claim 1 wherein said one or more anionic sulfur-containing surfactants is selected from the group consisting of linear alkylbenzenesulfonates (LAS), secondary alkylbenzenesulfonate, lignin sulfonates, N-acyl-N-alkyltaurates, fatty alcohol sulfates (FAS), petroleum sulfonates, secondary alkanesulfonates (SAS), paraffin sulfonates, fatty alcohol ether sulfates (FAES), α-Olefin sulfonates, sulfosuccinate esters, alkylnapthalenesulfonates, isethionates, sulfuric acid esters, sulfated linear primary alcohols, sulfated polyoxyethylenated straight chain alcohols, sulfated triglyceride oils and mixtures thereof.

3. The texturing composition of claim 1 wherein said one or more anionic sulfur-containing surfactants is selected from the group consisting of secondary alkanesulfonate sodium salts, diphenyl oxide disulfonic acids and ether sulfates.

4. The texturing composition of claim 1 wherein said texturing composition comprises hydrofluoric acid.

5. The texturing composition of claim 1 wherein said texturing composition comprises nitric acid and hydrofluoric acid.

6. The texturing composition of claim 1 wherein said one or more sulfur-containing surfactants have the following structure: 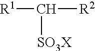
where R¹ and R² areindependently straight chain or cyclic alkyl groups or phenyl groups or combinations, typically comprising 1-20 carbons and X is hydrogen or any cation, including Na, K, tetramethyl ammonium, tetraethyl ammonium, triethanol amine, or ammonium.

7. The texturing composition of claim 1 wherein said one or more acids comprise one or more selected from the group consisting of phosphoric acid, sulfuric acid or a water-soluble carboxylic acid, for example acetic acid, propionic acid, butyric acid, valeric acid, caproic acid, tartaric acid, succinic acid, adipic acid, propane-tricarboxylic acid and an isomer of propane-tricarboxylic acid.

8. The texturing composition of claim 1 selected from the group consisting of (1) from about 37 to about 42 wt % of HF, from about 3.5 to about 7 wt % of HNO3, from about 0.005 to about 0.25 wt % of surfactant, and the balance is water; (2) from about 24 to about 30 wt % of HF, from about 14 to about 19 wt % of HNO3, from about 0.005 to about 0.25 wt % surfactant and the balance is water, and (3) from about 9 to about 13 wt % of HF, from about 31 to about 39 wt % HNO3, from about 0.005 to about 0.25 wt % surfactant, and the balance is water.

9. The texturing composition of claim 8 wherein said one or more sulfur-containing surfactants is selected from the group consisting of linear alkylbenzenesulfonates (LAS), secondary alkylbenzenesulfonate, lignin sulfonates, N-acyl-N-alkyltaurates, fatty alcohol sulfates (FAS), petroleum sulfonates, secondary alkanesulfonates (SAS), paraffin sulfonates, fatty alcohol ether sulfates (FAES), α-Olefin sulfonates, sulfosuccinate esters, alkylnapthalenesulfonates, isethionates, sulfuric acid esters, sulfated linear primary alcohols, sulfated polyoxyethylenated straight chain alcohols, sulfated triglyceride oils and mixtures thereof.

10. The texturing composition of claim 8 wherein said one or more sulfur-containing surfactants is selected from the group consisting of secondary alkanesulfonate sodium salt, diphenyl oxide disulfonic acid and ether sulfates.

11. A method of texturing a silicon wafer comprising the step of:
wetting said wafer with a texturing composition comprising one or more acids, one or more anionic sulfur-containing surfactants, and water.

12. The method of claim 11 wherein said sulfur-containing surfactants is selected from the group consisting of linear alkylbenzenesulfonates (LAS), secondary alkylbenzenesulfonate, lignin sulfonates, N-acyl-N-alkyltaurates, fatty alcohol sulfates (FAS), petroleum sulfonates, secondary alkanesulfonates (SAS), paraffin sulfonates, fatty alcohol ether sulfates (FAES), α-Olefin sulfonates, sulfosuccinate esters, alkylnapthalenesulfonates, isethionates, sulfuric acid esters, sulfated linear primary alcohols, sulfated polyoxyethylenated straight chain alcohols, sulfated triglyceride oils and mixtures thereof.

13. The method of claim 11 wherein said one or more sulfur-containing surfactants is selected from the group consisting of secondary alkanesulfonate sodium salt, diphenyl oxide disulfonic acid and ether sulfate, and said one or more acids comprises hydrofluoric acid.

14. The method of claim 11 further comprising the step of:
wetting the wafer with a second texturing composition, referred to as a second wetting step, following the wetting step with said texturing composition, referred to as a first wetting step.

15. The method of claim 14 wherein said second texturing composition comprises one or more bases in solvent.

16. The method of claim 14 further comprising the steps of:
rinsing the wafer after the first wetting step and before the second wetting step, and further rinsing and drying the wafer after the second wetting step.

17. The method of claim 10 wherein said texturing composition is selected from the group consisting of: (1) from about 37 to about 42 wt % of HF, from about 3.5 to about 7 wt % of HNO3, from about 0.005 to about 0.25 wt % of surfactant, and the balance is water; (2) from about 24 to about 30 wt % of HF, from about 14 to about 19 wt % of HNO3, from about 0.005 to about 0.25 wt % surfactant and the balance is water, and (3) from about 9 to about 13 wt % of HF, from about 31 to about 39 wt % HNO3, from about 0.005 to about 0.25 wt % surfactant, and the balance is water.

18. The method of claim 17 wherein said texturing composition used in the second texturing step is an aqueous hydroxide solution.
